(19) United States
(12) Patent Application Publication
(10) Pub. No.: US 2012/0013361 A1
(43) Pub. Date: Jan. 19, 2012

(54) Synthetic Pulse Generator for Reducing Supply Noise

(75) Inventor: Frederick A. Ware, Los Altos Hills, CA (US)

(73) Assignee: RAMBUS INC, SUNNYVALE, CA (US)

(21) Appl. No.: 13/148,510

(22) PCT Filed: Jan. 14, 2010
(86) PCT No.: PCT/US10/21024

§ 371 Date: Aug. 9, 2011

Related U.S. Application Data
(60) Provisional application No. 61/154,958, filed on Feb. 24, 2009.

(51) Int. Cl. H03K 19/003

(52) U.S. Cl. 326/30

(57) ABSTRACT

A source-terminated transmitter conveys digital signals over a short channel as a voltage signal that transitions between levels for each symbol transition. The transmitter produces each transition by issuing a charge pulse onto the channel, and thus creates a series of charge pulses. The number of charge pulses per unit time is proportional to the transition density of the signal, as no charge pulse is required between like symbols. The supply current used to deliver the pulses is therefore dependent upon the data pattern. This data dependency can induce supply fluctuations, which can in turn cause errors and otherwise reduce performance. The transmitter issues a synthetic charge pulse for each adjacent pair of like symbols to reduce the data dependency of the supply current. The synthetic pulses can be scaled to match the charge required for symbol transitions on a given channel.

### FIELD

The subject matter disclosed herein relates generally to the field of communications, and more particularly to high speed electronic signaling within and between integrated circuit devices.

### BACKGROUND

Serial communication circuits—transmitters and receivers—communicate data as a sequence of symbols, or symbol patterns. For example, a transmitter can transmit a series of binary bits—a bit pattern—by alternating between two voltage levels over time, with each level representing one of the two possible binary values for a single bit. The resultant voltage signal can then be sensed remotely to recover the original bit pattern.

In some communication circuits, switching between alternate voltage levels to express a bit transition from one to zero or vice versa requires the transmitter to draw current from a power supply. The number of transitions per unit time changes with the data pattern, so the power-supply current per unit time also changes. For example, the bit pattern 0011b includes only one transition, from zero to one, whereas the bit pattern 0101b requires three. The latter pattern would therefore require a transmitter to draw more supply current then the former to express the patterns as varying voltage signals. The supply current is therefore said to be “data-dependent.”

Power supplies and the wires they use to supply current exhibit impedances to the supply current. Drawing the data-dependent supply current through these non-zero impedances causes the supply voltage to exhibit a data-dependent component (i.e., the supply voltage is data-dependent). The data dependent fluctuation of the regulated voltage is undesirable. In a transmitter, for example, supply-voltage fluctuations may distort both the amplitude and transition timing for a transmitted signal, and thus induce errors, reduce speed performance, or both.

### BRIEF DESCRIPTION OF THE DRAWINGS

The subject matter disclosed is illustrated by way of example, and not by way of limitation, in the figures of the accompanying drawings and in which like reference numerals refer to similar elements and in which:

FIG. 1 depicts a differential communication system 100 in accordance with one embodiment.

FIG. 2 depicts a communication system 200 in accordance with another embodiment.

FIG. 3 is a waveform diagram 300 illustrating the operation of IC 205 of FIG. 2 in accordance with one embodiment.

FIG. 4 depicts an IC 400 in accordance with another embodiment. IC 400 includes a data source 405 that serializes parallel data Dtx[7:0] and provides the resulting serial data Dtx(n) to a differential transmitter 410 on rising and falling edges of a clock signal on node CK.

FIG. 5 is a waveform diagram 500 illustrating the operation of IC 400 when transmitting the eight-bit word D[7:0] equal to 01000111b.

### DETAILED DESCRIPTION

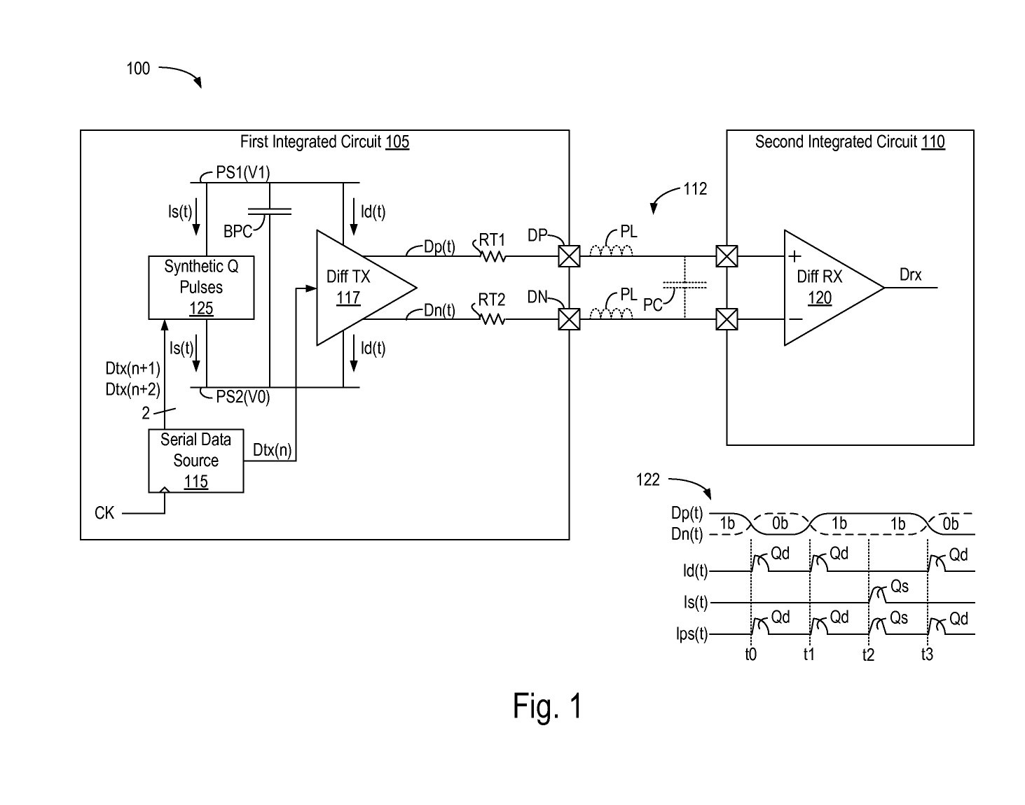

FIG. 1 depicts a differential communication system 100 in accordance with one embodiment. A pair of integrated circuits (ICs) 105 and 110 employs differential signaling to communicate over two separate wires of a communication channel 112. Differential signaling is commonly used in high-speed digital systems, but can also be used for analog channels. Differential signaling is particularly advantageous for use with low supply voltages. Supply voltages are low and getting lower in mobile devices because lower voltages facilitate power savings and reduce extraneous radiation. The importance of differential signaling is therefore expected to grow with the market for mobile devices. ICs 105 and 110 might be e.g. an application processor in a cell phone, or a processor or memory controller in a portable computer. IC 110 might be e.g. a memory component, such as a DRAM or flash device.

IC 105 includes some form of serial data source 115 that provides serial transmit data Dtx(n) to a differential transmitter 117. Transmitter 117 conveys the serial data as two complementary signals Dp(t) and Dn(t) on like-named output nodes. Node Dp(t) is connected to one of the two conductors of channel 112 via a termination resistor RT1 and a pad DP. Node Dn(t) is likewise connected via a termination resistor RT2 and pad DN. Complementary data signals conveyed over channel 112 ultimately arrive at the input nodes of a differential receiver 120, which recovers transmitted data Dtx as receive data Drx. Receiver 120 is entirely conventional in this example, and differential amplifiers are well understood by those of skill in the art.

A waveform diagram 122 in the lower right of FIG. 1 illustrates how some of the key signals of system 100 interact in the depicted embodiment to send a serial binary pattern Dtx=10110b. As shown by the top row Dp(t)/Dn(t), the differential output from transmitter 117 represents the serial of symbols by alternating each of nodes Dp(t) and Dn(t) between two levels, voltage levels in this example. Transmitter 117 makes the requisite voltage changes by switching data current Id(t) between two supply nodes PS1 and PS2. The voltage changes are opposed by termination resistors RT1 and RT2, parasitic inductances PL, and parasitic capacitance PC. Transmitter 117 draws sufficient charge to oppose these collective channel impedances and charge capacitance PC to either voltage V1-V0 or V0-V1, depending upon the logic value represented by the symbol.

Current Id(t) stops flowing when the voltages on nodes Dp(t) and Dn(t) reach their respective target values. For relatively short channels, this means that data current Id(t) may flow only intermittently and for a fraction of a bit time, where a “bit time” is the duration of one symbol. With reference to waveform diagram 122, data current Id(t) is not constant, but instead consists of data charge pulses Qd that occur at symbol transitions to reverse the voltage potential of nodes Dp(t) and Dn(t). Because no charge is required to maintain signals Dp(t) and Dn(t) when data does not transition between symbols, as shown at time t2, data current Id(t) does not evince a data charge pulse Qd at time t2. The number of data charge pulses per unit time is proportional to the transition density of the transmitted data pattern, so data current Id(t) is data dependent.

As noted previously, data-dependent supply current induces supply-voltage fluctuations that can cause errors and otherwise reduce performance. To combat this problem, integrated circuit 105 includes a synthetic charge-pulse generator 125 connected between power-supply nodes PS1 and PS2 in parallel with transmitter 117. Pulse generator 125 identifies adjacent like symbols to be transmitted by serial data source 115, and can consequently tell when nodes Dp(t) and Dn(t) will not transition for a given bit interval. In this example pulse generator 125 considers adjacent symbols Dtx(n+1) and Dtx(n+2), the two adjacent symbols subsequent to the current symbol Dtx(n), but other symbols and symbol patterns might also be used.

Referring again to diagram 122 and recalling that nodes Dp(t) and Dn(t) do not transition at time t2, pulse generator 125 notes the absence of a transition and draws a “synthetic” charge pulse Qs as supply current Is(t) at time t2. The magnitude of synthetic charge pulse Qs—the amount of charge drawn from the supply—is scaled to approximate the magnitude of one data charge pulse Qd. The data and synthetic charge pulses thus appear about the same from the perspective of the power-supply. Because the supply sees a data charge pulse Qd for each symbol that transitions and a synthetic charge pulses Qs for each symbol that does not, the load on the power-supply network exhibits little or no data dependency. The reduced supply fluctuations improve the performance of transmitter 117.

The power-supply network of IC 105 may include considerable bypass capacitance BPC to filter out supply noise. The frequency response of the supply network is largely a function of parasitic lead inductance external to IC 105, but is also a function of e.g. bypass capacitance BPC and parasitic resistance and capacitance (not shown). The data rates can be sufficiently high relative to the frequency response of the power-distribution network that the effects of the data and synthetic charge pulses are essentially filtered out. This filtering effect also means that the phase alignment of the synthetic pulses with respect to the data pulses is not critical.

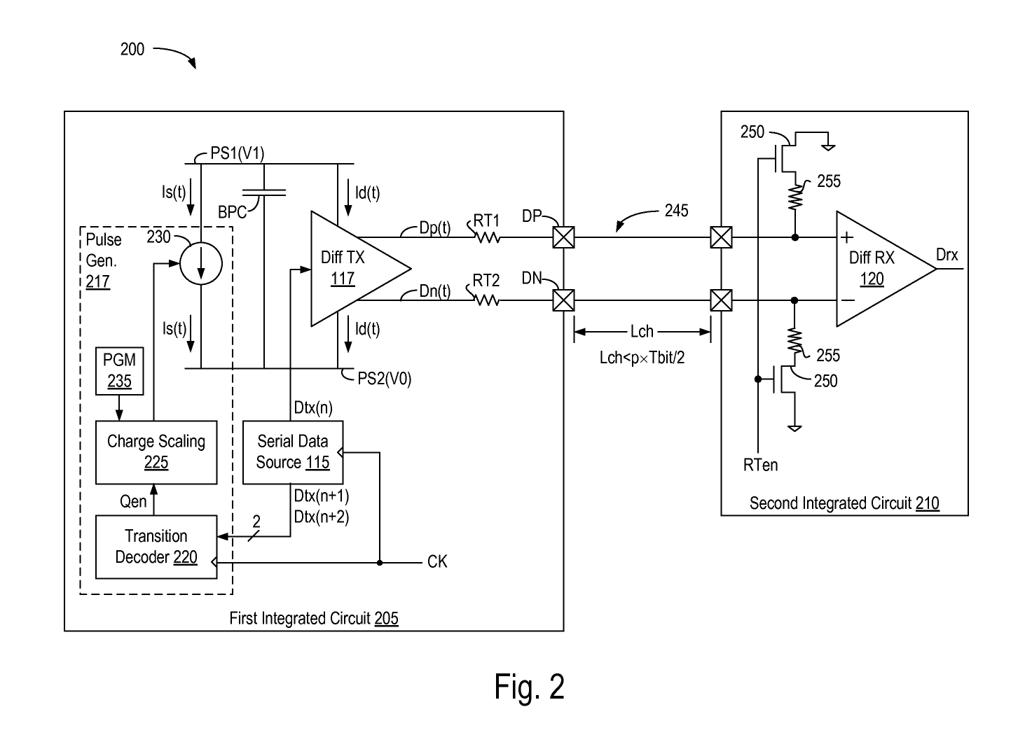

FIG. 2 depicts a communication system 200 in accordance with another embodiment. System 200 includes first and second ICs 205 and 210 that are similar to corresponding ICs 105 and 110 of FIG. 1, with like-labeled elements being the same or similar. IC 205 includes a pulse generator 217 that produces a synthetic charge pulse between supply nodes PS1 and PS2 each time data signal Dtx(n) fails to transition between adjacent symbols. Pulse generator 217 accomplishes this using a transition decoder 220, a charge scaling circuit 225, and a variable current sink 230. Pulse generator further includes a programmable storage element 235, such as a register, that can be used to set the magnitude of charge for each synthetic pulse Qs to match the amount of charge Qd associated with each data transition. This flexibility advantageously allows IC 205 to calibrate the synthetic charge pulses to accommodate different channels. For example, longer channels tend to require more time and a greater quantity of charge to transition between symbols. Pulse generator 217 can thus be adjusted to produce synthetic charge pulses of a greater magnitude for longer channels. Storage element 235 can also disable pulse generator 217 in some embodiments. Reasons for disabling synthetic-pulse generation are discussed below.

Transmitter 117 is source terminated via resistors RT1 and RT2, and is coupled to a selectively terminated differential receiver 120 via a channel 245 of length Lch. Synthetic charge pulses are used in this embodiment for relatively short channels: channel length Lch is less than about half the product of the bit-time Tbit and the signal-propagation velocity p through channel 245 (Lch<(p×Tbit/2)). At the destination end of channel 245, a termination-enable signal RTen can be asserted to enable a pair of transistors 250, and consequently to provide parallel termination for amplifier 120 via termination resistors 255. Signal RTen can be controlled via a register, for example, to selectively provide for parallel termination. Synthetic charge pulses are disabled and parallel termination enabled for longer channels (Lch≧(p×Tbit/2)).

Pulse generator 217 inserts scaled synthetic charge pulses Qs between supply nodes PS1 and PS2 for each adjacent pair of like bits. To do this, transition decoder 220 issues a charge-enable signal Qen to charge-scaling circuit 225 each time the next two symbols Dtx(n+1) and Dtx(n+2) are the same.

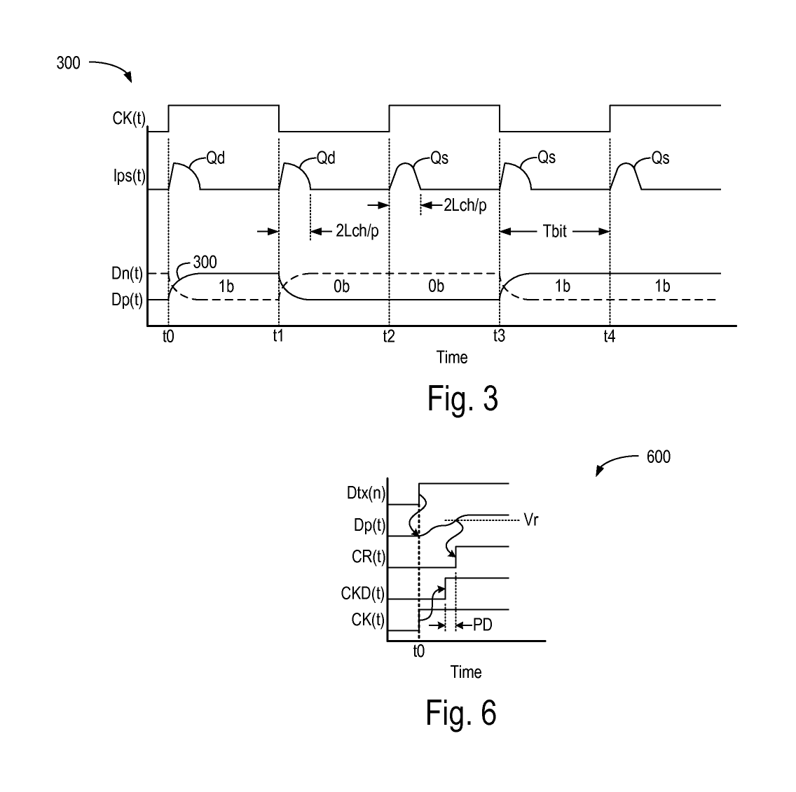

FIG. 3 is a waveform diagram 300 illustrating the operation of IC 205 of FIG. 2 in accordance with one embodiment. The following discussion assumes a short, source-terminated channel with signal RTen de-asserted and synthetic pulse generator 217 enabled. Short channels benefit from source-only termination because essentially no current flows into the channel once the output voltage peaks.

The bit time Tbit of system 200 is half the period of clock signal CK(t) in this embodiment, with data symbols transmitted synchronously with respect to both rising and falling clock edges. Symbols may be transmitted synchronously with respect to only rising edges or falling edges in other embodiments. (As with other signal/node pairs, signal CK(t) and the corresponding nodes CK have similar labels.) The example of diagram 300 illustrates the transmission of data pattern Dtx(n) of 10011b, which is conveyed over channel 245 as a differential signal Dp(t)/Dn(t). Power-supply current Ips(t), the sum of synthetic and data currents Is(t) and Id(t), evinces a data charge pulse Qd at the transitions of signal Dp(t)/Dn(t) and a synthetic charge pulse Qs at times t2 and t4 when there is no data transition. The amount of charge conveyed in each pulse Qd is proportional to the channel length Lch. Charge is scaled in this embodiment by adjusting pulse length. For example, longer channels requiring more charge receive longer charge pulses. In the example of FIG. 3, data charge pulses Qd have an approximate duration of 2Lch/p, and the duration synthetic charge pulses Qs are scaled to match. The data and synthetic currents Id(t) and Is(t) are of similar magnitudes and the corresponding pulses of similar duration, so the data and synthetic charge pulses Qs and Qd deliver about the same quantity of charge between the supply terminals. In other embodiments the charge for each synthetic pulse can be scaled by e.g., making an adjustment in current Is(t).

Source termination saves power for short channels because supply current quickly approaches zero after each symbol transition. As depicted in FIG. 3, even with synthetic current pulses Qs inserted to reduce supply noise, supply current Ips is approximate zero most of the time. A disadvantage of source termination is that the receive end of the channel does not see the full signal amplitude for as long as twice the propagation delay of the channel. The resulting delay limits speed performance for longer channels. Source termination is therefore less desirable for longer channels.

The embodiment of FIG. 2 supports two types of termination: source termination alone for short channels and both source and receive-side termination for longer channels. For short channels, pulse generator 217 is enabled and parallel termination resistors 255 disabled. For longer channels, receive-side termination is more important for signal integrity and has a smaller power impact. System 200 can be configured for longer channels by disabling pulse generator 217 and enabling termination resistors 255. System 200 thus offers performance optimization for different channel lengths.

Portable platforms, such as cell phones, smart phones, media players, and game consoles can benefit from circuits and methods of the types described herein. Non-portable systems with high bandwidth-to-capacity ratios, such as graphics cards for desktop computers, might also benefit.

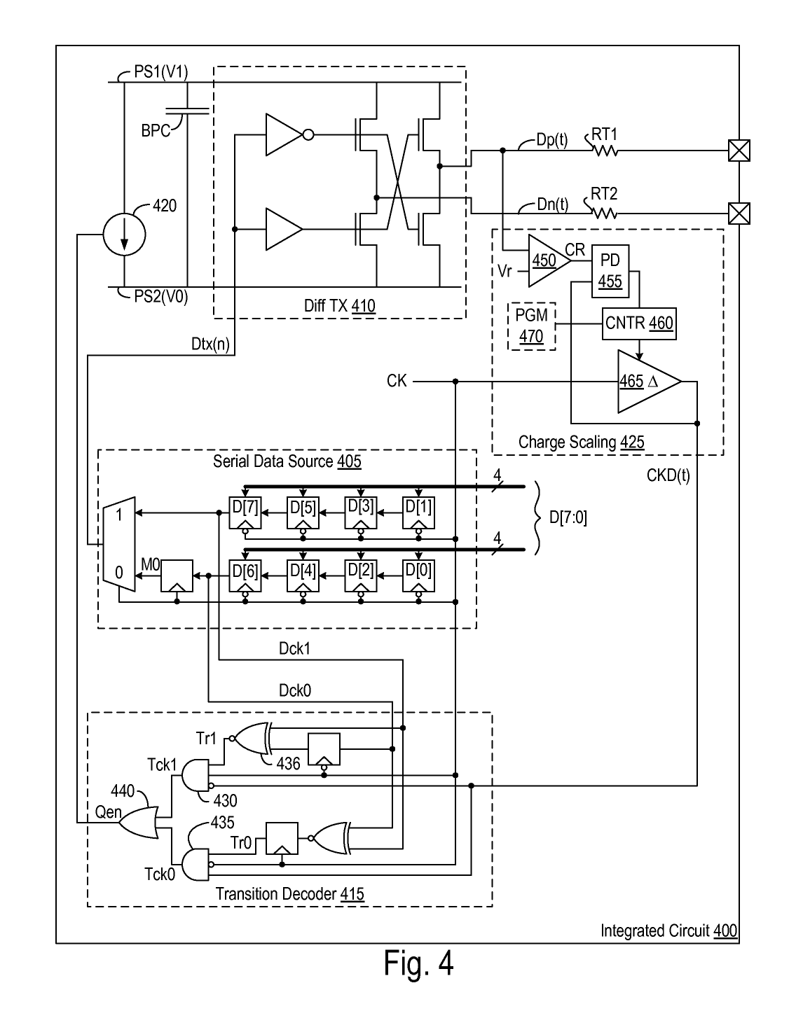

FIG. 4 depicts an IC 400 in accordance with another embodiment. IC 400 includes a data source 405 that serializes parallel data Dtx[7:0] and provides the resulting serial data Dtx(n) to a differential transmitter 410 on rising and falling edges of a clock signal on node CK. Data source 405 loads eight bits of data Dtx[7:0] in parallel, four bits to each of two sets of registers, and then shifts the stored bits out through a multiplexer on alternate edges of the clock signal. Transmitter 410 amplifies the serial data stream and conveys the resulting amplified symbols as a differential signal Dp(t)/Dn(t) in the manner discussed above in connection with the embodiment of FIGS. 1 and 2.

As in previous examples, dissimilar adjacent bits represented by signal Dp(t)/Dn(t) cause the power supply to issue data charge pulses Qd, whereas similar adjacent bits do not. This leads to an undesirable data-dependency of the supply current. IC 400 addresses this problem with a transition decoder 415 that detects the occurrence of similar adjacent bits and, responsive to these events, causes a current sink 420 to draw a synthetic charge pulse Qs of a magnitude that approximates the charge pulses associated with symbol transitions. A charge scaling circuit 425 is included to determine the appropriate size of the synthetic charge pulses and to scale them accordingly. In this example, the scaling is accomplished by measuring the signal-propagation delay of the associated channel (not shown) and matching the duration of the synthetic charge pulses to the propagation delay.

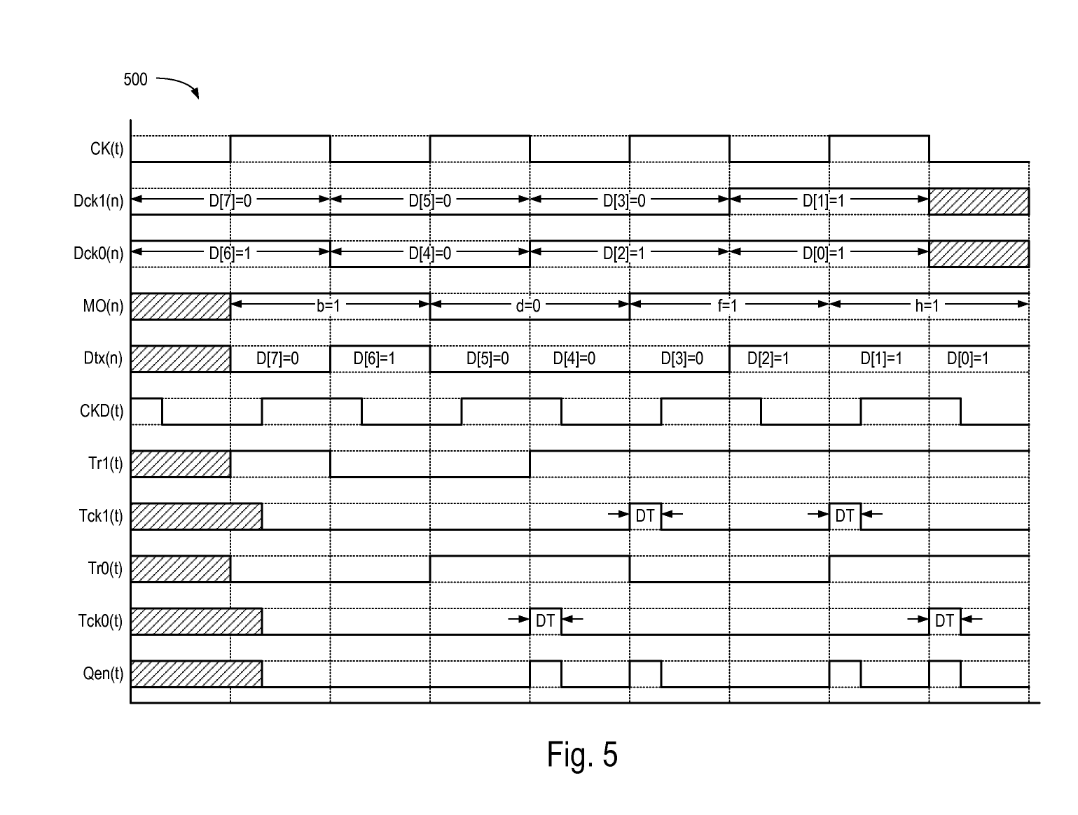

FIG. 5 is a waveform diagram 500 illustrating the operation of IC 400 when transmitting the eight-bit word D[7:0] equal to 01000111b. Returning to FIG. 4, transition decoder 415 identifies instances of adjacent like symbols. When clock signal CK goes high, the output Tck1 of AND gate 430 will go high for a time DT if the output of an XOR gate 436 is high, which happens if the current symbol Dtx(n) and the preceding symbol Dtx(n−1) are of the same value. When clock signal CK goes low, the output Tck0 of AND gate 435 will likewise go high for a time DT its input Tr0 is high, which happens if the current and preceding symbols match. An OR gate 440 combined the outputs from gates 430 and 435 to produce a pulse-enable signal Qen that controls current sink 420.

Charge scaling circuit 425 defines the length of each pulse on node Qen, and thus each synthetic pulse Qs, using a comparator 450, a phase detector 455, a counter 460, an adjustable delay element 465, and an optional programming register 470. The duration of time DT is set by the delay through delay element 465. Each of AND gates 430 and 435 in transition decoder 415 receives a third input from a clock signal CKD(t), a version of clock signal CK(t) delayed by the time DT used to select the quantity of charge passed by sink 420 for each adjacent pair of like symbols. The delayed clock signal de-asserts signals Tck1 and Tck0, and thus terminates the enable pulses on node Qen.

FIG. 6 is a waveform diagram 600 depicting the operation of charge scaling circuit 425 of FIG. 5 during a calibration process for scaling the synthetic charge pulses. Clock signal CK(t) and data Dtx(n) transition high at time t0. Transmitter 410 amplifies the data transition onto the differential channel (not shown) as complementary signal halves Dp(t)/Dn(t). Signal Dp(n) thus begins charging the channel, remaining below a reference voltage Vr until the transmitted pulse is reflected back to the source. The longer the channel, the greater the delay between the rising edge of signal Dtx(n) and the time at which signal Dp(t) reaches threshold Vr. When signal Dtx(n) reaches the threshold, the output node CR of comparator 450 transitions high.

Delay element 465 delays the rising edge of clock signal CK(t) by a duration set by the contents of counter 460. In this example, the delayed edge of clock signal CKD(t) goes high before the output CR of comparator 450. Phase detector 455 notes the phase disparity and increments counter 460, which in turn increases the delay imposed by delay element 465. The phase disparity approaches zero as more corresponding data and clock edges are fed through scaling circuit 425. Because the delay through element 465 is proportional to the delay through the channel, the delay DT is likewise proportional to the delay through the channel. The amount of charge per synthetic charge pulse Qs can be adjusted by e.g. inserting a phase offset or adjusting the reference voltage Vr. The calibration procedure can be done once or repeated to accommodate e.g. temperature changes of supply drift. Register 470 can be included to set the phase offset or to disable charge scaling for longer channels.

In the foregoing description and in the accompanying drawings, specific terminology and drawing symbols are set forth to provide a thorough understanding of the foregoing embodiments. In some instances, the terminology and symbols may imply specific details that are not required to practice the invention. For example, the interconnection between circuit elements or circuit blocks may be shown or described as multi-conductor or single conductor signal lines. Each of the multi-conductor signal lines may alternatively be single-conductor signal lines, and each of the single-conductor signal lines may alternatively be multi-conductor signal lines. Signals and signaling paths shown or described as being single-ended may also be differential. Similarly, signals described or depicted as having active-high or active-low logic levels may have opposite logic levels in alternative embodiments. As another example, circuits described or depicted as including metal oxide semiconductor (MOS) transistors may alternatively be implemented using bipolar technology or any other technology in which a signal-controlled current flow may be achieved. With respect to terminology, a signal is said to be “asserted” when the signal is driven to a low or high logic state (or charged to a high logic state or discharged to a low logic state) to indicate a particular condition. Conversely, a signal is said to be “de-asserted” to indicate that the signal is driven (or charged or discharged) to a state other than the asserted state (including a high or low logic state, or the floating state that may occur when the signal driving circuit is transitioned to a high impedance condition, such as an open drain or open collector condition).

An output of a process for designing an integrated circuit, or a portion of an integrated circuit, comprising one or more of the circuits described herein may be a computer-readable medium such as, for example, a magnetic tape or an optical or magnetic disk. The computer-readable medium may be encoded with data structures or other information describing circuitry that may be physically instantiated as an integrated circuit or portion of an integrated circuit. Although various formats may be used for such encoding, these data structures are commonly written in Caltech Intermediate Format (CIF), Calma GDS II Stream Format (GDSII), or Electronic Design Interchange Format (EDIF). Those of skill in the art of integrated circuit design can develop such data structures from schematic diagrams of the type detailed above and the corresponding descriptions and encode the data structures on computer readable medium. Those of skill in the art of integrated circuit fabrication can use such encoded data to fabricate integrated circuits comprising one or more of the circuits described herein.

While the present invention has been described in connection with specific embodiments, variations of these embodiments will be obvious to those of ordinary skill in the art. For example, transmitters with synthetic pulse generators can be used in support of multiwire differential signaling, examples of which are described in a paper entitled “Multiwire Differential Signaling,” by John W. Poulton, Stephen Tell, and Robert Palmer (Revision 1.1—Aug. 6, 2003). Moreover, some components are shown directly connected to one another while others are shown connected via intermediate components. In each instance the method of interconnection, or “coupling,” establishes some desired electrical communication between two or more circuit nodes, or terminals. Such coupling may often be accomplished using a number of circuit configurations, as will be understood by those of skill in the art. Therefore, the spirit and scope of the appended claims should not be limited to the foregoing description. For U.S. applications, only those claims specifically reciting “means for” or “step for” should be construed in the manner required under the sixth paragraph of 35 U.S.C. §112.

What is claimed is:

1. An integrated circuit comprising:
a data source having a data node to convey symbols as a serial data stream;
a transmitter coupled to first and second power-supply nodes, the transmitter having:
an input node, coupled to the data node, to receive the serial data stream;
first and second output nodes to convey the serial data stream as a series of symbols;
a first termination resistor connected between the first output node and a first signal pad; and
a second termination resistor connected between the second output node and a second signal pad;
a control circuit coupled to the first and second power-supply nodes and including a current-control port, the control circuit to draw charge from the first power-supply node to the second power-supply node responsive to a current-control signal; and
a decoder coupled to the data source and the current-control port, the decoder to adjust the current-control signal to alter the charge drawn over time in proportion to a concentration of adjacent like symbols in the serial data stream.

2. The integrated circuit of claim 1, further comprising a charge-scaling circuit to scale the charge.

3. The integrated circuit of claim 2, wherein the decoder alters the charge by intermittently enabling the current sink for an interval, and wherein the charge-scaling circuit sets the interval to scale the charge.

4. The integrated circuit of claim 3, wherein the decoder enables the current sink for the interval responsive to each pair of adjacent like symbols.

5. The integrated circuit of claim 2, wherein the first and second signal pads are to connect to a channel to convey the series of symbols, each symbol traversing the channel in a propagation delay, and wherein the charge-scaling circuit includes a measurement circuit to measure the propagation delay.

6. The integrated circuit of claim 1, further comprising a programming element to prevent the current sink from altering the charge drawn from the first power-supply node.

7. An integrated circuit comprising:
a data source having a data node to convey the symbols as a serial data stream;
a differential transmitter disposed between first and second power-supply nodes, the differential transmitter having:
an input node, coupled to the data node, to receive the serial data stream;
first and second output nodes to convey the serial data stream as a series of differential symbols, wherein the transmitter transfers data charge pulses between the first and second power-supply nodes responsive to transitions between adjacent symbols in the serial data stream;
a first termination resistor connected between the first output node and a first signal pad; and
a second termination resistor connected between the second output node and a second signal pad; and
a charge-pulse generator coupled to the first and second power-supply terminals and having a control port coupled to the serial data source, the charge-pulse generator to transfer synthetic charge pulses from the first to the second power-supply terminal responsive to adjacent like symbols in the serial data stream.

8. The integrated circuit of claim 7, wherein each synthetic charge pulse conveys a quantity of charge equal to that of a data charge pulse.

9. The integrated circuit of claim 7, wherein the transitions are spaced in increments of a bit time, and wherein the synthetic and data charge pulses are of a duration less than the bit time.

10. The integrated circuit of claim 9, wherein the durations of the synthetic and data charge pulses are equal.

11. The integrate circuit of claim 7, wherein the synthetic charge pulses are temporally between the data charge pulses.

12. The integrated circuit of claim 11, wherein the synthetic charge pulses do not overlap the data charge pulses.

13. The integrated circuit of claim 7, wherein the charge-pulse generator further comprises a charge-scaling circuit to match that synthetic and data charge pulses.

14. A method of operation on an integrated circuit, the method comprising:
providing serial transmit data to a transmitter;
transmitting the serial transmit data, with the transmitter, as a data signal having symbol transitions with a minimum spacing of a bit time, wherein the transmitter draws data charge pulses of a data-pulse magnitude from a power supply to produce the symbol transitions, the data charge pulses having a data-pulse duration less than the bit time; and
drawing synthetic charge pulses from the power supply between the data charge pulses.

15. The method of claim 14, wherein the synthetic charge pulses have a synthetic-pulse magnitude, the method further comprising scaling the synthetic-pulse magnitude to match the data-pulse magnitude.

16. The method of claim 15, wherein the synthetic charge pulses have a charge-pulse duration less than the bit time.

17. The method of claim 15, further comprising scaling the charge-pulse duration to match the data-pulse duration.

18. The method of claim 14, wherein the transmitter transmits the serial transmit data as a differential signal.

19. A circuit comprising:
a power supply;
a transmitter coupled to the power supply, the transmitter to transmit a serial data signal having symbol transitions with a minimum spacing of a bit time, wherein the transmitter draws data charge pulses of a data-pulse magnitude from the power supply to produce the symbol transitions, the data charge pulses having a data-pulse duration less than the bit time; and
means for drawing synthetic charge pulses from the power supply between the data charge pulses.

20. The circuit of claim 19, wherein the means for drawing the synthetic charge pulse includes means for scaling the synthetic charge pulses to match the data-charge pulses.

21. The circuit of claim 19, wherein the synthetic charge pulses have a synthetic-charge duration, and wherein the means for scaling the synthetic charge pulses to match the data-charge pulses matches the synthetic-charge duration to the data-pulse duration.

22. The circuit of claim 19, wherein the means for drawing the synthetic charge pulse includes a programmable storage element to set a magnitude of the synthetic charge pulses.

23. The circuit of claim 22, wherein the programmable storage element sets the magnitude by adjusting a length of the synthetic charge pulses.

24. An integrated circuit comprising:
a power supply;
a transmitter, coupled to the power supply, to transmit a series of symbols of a first symbol type and of a second symbol type, wherein the transmitter draws a data charge pulse of a data-pulse magnitude from the power supply to produce a symbol transition between each symbol of the first symbol type and an adjacent symbol of the second symbol type; and
a synthetic-pulse generator coupled to the power-supply, wherein the synthetic-pulse generator draws a synthetic charge pulse of a synthetic-pulse magnitude from the power supply for each adjacent pair of symbols of the first symbol type and each adjacent pair of symbols of the second symbol type.

25. The integrated circuit of claim 24, wherein the synthetic-pulse generator includes a charge-scaling circuit for scaling the synthetic-pulse magnitude to match the data- pulse magnitude.

26. The circuit of claim 25, wherein the charge-scaling circuit adjusts a duration of the synthetic charge pulses to scale the synthetic-pulse magnitude.

27. The circuit of claim 26, wherein the charge-scaling circuit includes a register to set the duration.

28. An integrated circuit comprising:
a transmitter coupled to a first power-supply node and a second power-supply node, the transmitter to output a serial data stream;
a circuit coupled to the transmitter, the circuit to transfer a synthetic charge pulse from the first power-supply node to the second power-supply node based on an occurrence of a predetermined data pattern in the serial data stream; and
a register to store a value that represents the duration of the synthetic charge pulse.

29. The circuit of claim 28, wherein the serial data stream comprises symbols of a plurality of symbols types, and wherein the predetermined data pattern consists of two adjacent symbols of one of the symbol types.
